(19) United States
(12) Patent Application Publication
(10) Pub. No.: US 2008/0191262 A1
(43) Pub. Date: Aug. 14, 2008

(54) NON-VOLATILE MEMORY AND FABRICATING METHOD THEREOF

(75) Inventors: Ko-Hsing Chang, Hsinchu City (TW); Chiu-Tsung Huang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: POWERCHIP SEMICONDUCTOR CORP., Hsinchu (TW)

(21) Appl. No.: 11/768,179

(22) Filed: Jun. 25, 2007

(30) Foreign Application Priority Data
Feb. 9, 2007 (TW) 96104759

(51) Int. Cl. H01L 29/788; H01L 21/8246

(52) U.S. Cl. 257/316; 438/257; 257/E29.3; 257/E21.679

(57) ABSTRACT

The invention provides a non-volatile memory including a substrate, an active layer, device isolation layers and memory cells. The active layer disposed on the substrate protrudes from the substrate surface. Regarding the active layer, the device isolation layers are respectively disposed on the two sides thereof; the surface of the device isolation layers is lower than that of the active layer; the charge storage layer is disposed on the sidewalls thereof between the control gate and the active layer; the cap layer is disposed in the top section thereof between the control gate and the active layer, and the source/drain region is disposed in the active layer at the two sides of the control gate. Each of the memory cells includes a control gate, a charge storage layer, a cap layer and a source/drain region. The control gate disposed on the substrate crosses over the active layer.

### CROSS-REFERENCE TO RELATED APPLICATION

This application claims the priority benefit of Taiwan application serial no. 96104759, filed Feb. 9, 2007. All disclosure of the Taiwan application is incorporated herein by reference.

### BACKGROUND OF THE INVENTION

1. Field of the Invention

The present invention relates to a semiconductor device, more particularly, to a non-volatile memory and a method of fabricating the same.

2. Description of Related Art

Among various kinds of memory products, the non-volatile memory is a kind of memory characterized by the advantages that it allows multiple data storing, reading or erasing operations and the stored data therein will be retained after the power to device is cut off. Hence, the non-volatile memory has become a widely adopted memory device in personal computers and electronic equipments.

In the typical EEPROM, doped polysilicon is used to fabricate a floating gate and a control gate.

In the conventional technologies, a charge trapping layer is also used to replace the polysilicon floating gate. The material of the charge trapping layer is, for example, silicon nitride. The silicon nitride charge trapping layer usually has a silicon oxide layer on its top surface and bottom surface respectively, thus forming an oxide-nitride-oxide (ONO) composite layer. The kind of device is usually called silicon/oxide-nitride-oxide/silicon (SONOS) device. Since silicon nitride has a characteristic of trapping electrons, the electrons injected into the charge trapping layer would concentrate in a partial area of the charge trapping layer.

In the other aspect, the non-volatile memory commonly used by the industry includes the NOR type and the NAND type array structures. Since each of the memory cells is serially connected by the NAND-type array non-volatile memory structure, and the level of integration and the area utilization thereof are better than those of the NOR-type array non-volatile memory, it has been widely applied in various kinds of electronic products. However, the procedures of writing and reading the memory cells in the NAND-type array are more complicated and many memory cells are connected in series in the array. As a result, read currents of the memory cells are therefore smaller, which in turn leads to the slowing down of the memory cell operating speed and failure to improve the efficiency of the device.

### SUMMARY OF THE INVENTION

The present invention provides a non-volatile memory and a fabricating method thereof, which reduces the size of the memory cell and increase the level of integration of devices.

The invention provides a non-volatile memory and a fabricating method thereof to obtain larger read currents when a reading operation is performed in the memory cells and improve the efficiency of the device.

The invention provides a non-volatile memory and a fabricating method thereof. The fabricating process is simple and can reduce the production cost.

The invention provides a non-volatile memory including a substrate, an active layer, device isolation layers and memory cells. The active layer is disposed on the substrate and protrudes from the substrate surface. A plurality of device isolation layers is respectively disposed on the two sides of the active layer. Moreover, the surface of the device isolation layer is lower than the surface of the active layer. At least one memory cell is disposed on the substrate. The memory cell includes a control gate, a charge storage layer, a cap layer and source/drain regions. The control gate is disposed on the substrate and crosses over the active layer. The charge storage layer is disposed on the sidewalls of the active layer and located between the control gate and the active layer. The cap layer is disposed on the top section of the active layer and is located between the control gate and the active layer. The source/drain regions are disposed in the active layer at the two sides of the control gate.

In one embodiment of the invention, the non-volatile memory further includes a top dielectric layer. The top dielectric layer is disposed between the control gate and the charge storage layer. The material of the top dielectric layer includes silicon oxide.

In one embodiment of the invention, the non-volatile memory further includes a bottom dielectric layer. The bottom dielectric layer is disposed between the charge storage layer and the active layer. The material of the bottom dielectric layer includes silicon oxide.

In one embodiment of the invention, the material of the charge storage layer includes silicon nitride, tantalum silicon oxide, strontium silicon titanate or silicon oxide.

In one embodiment of the invention, the material of the device isolation layer includes silicon oxide.

The invention provides a non-volatile memory including a substrate, a plurality of active layers, a plurality of device isolation layers, a plurality of memory cell rows, a plurality of word lines, a plurality of bit lines and a plurality of source lines. The plurality of active layers is disposed on the substrate and protrudes from the substrate surface. The active layers are arranged in parallel in the row direction. The plurality of device isolation layers is respectively disposed on the two sides of the active layer. Moreover, the surface of the device isolation layer is lower than the surface of the active layer. The plurality of memory cell rows is respectively disposed on each of the active layers. Each of the memory cell rows includes a source region, a drain region and a plurality of memory cells. The source region and the drain region are disposed in the active layer. The plurality of memory cells is connected in series and disposed between the source region and the drain region. Each of the memory cells includes a control gate, a charge storage layer and doped regions. The control gate is disposed on the substrate and crosses over the active layer. The charge storage layer is disposed on the sidewalls of the active layer and located between the control gate and the active layer. The doped regions are disposed in the active layer at the two sides of the control gate. The plurality of word lines is disposed on the substrate. The word lines are arranged in parallel in the column direction and electrically connected with the control gate on the same column. The plurality of bit lines is disposed in parallel on the substrate. The bit lines are arranged in parallel in the row direction and electrically connected with the drain region in the same memory cell row. The plurality of source lines is disposed in parallel on the substrate. The source lines are arranged in parallel in the column direction and electrically connected with the source region on the same memory cell column.

In one embodiment of the invention, the outermost memory cell in each of the memory cell rows serves as a select unit. The word line connected with the select unit serves as a select gate line.

In one embodiment of the invention, each of the memory cell rows further includes two select units. The two select units are respectively disposed between the source region and the memory cells and between the drain region and the memory cells.

In one embodiment of the invention, each of the select units includes a select gate and a select gate dielectric layer. The select gate is disposed on the substrate and crosses over the active layer. The select gate dielectric layer is disposed on the sidewalls of the active layer and located between the select gate and the active layer.

In one embodiment of the invention, the non-volatile memory further includes a plurality of select gate lines. The select gate lines are disposed on the substrate, arranged in parallel in the column direction and electrically connected with the select gate on the same column.

In one embodiment of the invention, the material of the select gate dielectric layer includes silicon oxide.

In one embodiment of the invention, the non-volatile memory further includes a top dielectric layer. The top dielectric layer is disposed between the control gate and the charge storage layer. The material of the top dielectric layer includes silicon oxide.

In one embodiment of the invention, the non-volatile memory further includes a bottom dielectric layer. The bottom dielectric layer is disposed between the charge storage layer and the active layer. The material of the bottom dielectric layer includes silicon oxide.

In one embodiment of the invention, the material of the charge storage layer includes silicon nitride, tantalum silicon oxide, strontium silicon titanate or hafnium silicon oxide.

In one embodiment of the invention, the material of the device isolation layer includes silicon oxide.

In one embodiment of the invention, the non-volatile memory further includes a cap layer. The cap layer is disposed on the top section of the active layer and located between the control gate and the active layer. The material of the cap layer includes silicon nitride.

The fabricating method of the non-volatile memory disclosed in the present invention includes the following steps. A substrate is provided and an active layer is formed thereon. The active layer protrudes from the substrate surface. A plurality of device isolation layers are formed at the two sides of the active layer. The surface of the device isolation layers is lower than the surface of the active layer. A charge storage layer is formed on the substrate and a control gate is formed thereon. The control gate crosses over the active layer. Afterwards, a source/drain region is formed in the active layer at the two sides of the control gate.

In one embodiment of the invention, the method of forming the active layer on the substrate includes forming a plurality of trenches on the substrate.

In one embodiment of the invention, the method of fabricating the non-volatile memory further includes that a cap layer is formed in the top section of the active layer. The material of the cap layer includes silicon nitride.

In one embodiment of the invention, the method of fabricating the non-volatile memory further includes forming a top dielectric layer between the control gate and the charge storage layer. The material of the top dielectric layer includes silicon oxide.

In one embodiment of the invention, the method of fabricating the non-volatile memory further includes forming a bottom dielectric layer between the charge storage layer and the active layer. The material of the bottom dielectric layer includes silicon oxide.

In one embodiment of the invention, the material of the charge storage layer includes silicon nitride, tantalum silicon oxide, strontium silicon titanate or hafnium silicon oxide.

In one embodiment of the invention, the material of the device isolation layer includes silicon oxide.

The method of fabricating the non-volatile memory disclosed by the present invention includes the following steps. A substrate is provided, and a plurality of active layers is formed thereon. The active layers protrude from the substrate surface and are arranged in parallel in the row direction. A plurality of device isolation layers is formed at the two sides of the active layer. The surface of the device isolation layer is lower than the surface of the active layer. A charge storage layer is formed on the substrate, and a conductive layer is also formed on the substrate. The conductive layer is patterned to form a plurality of word lines. The word lines are arranged in parallel in the column direction and cross over the active layer. A plurality of doped regions is formed in the active layer at the two sides of the word lines. Memory cells are respectively formed in the intersections between the word lines and the active layers.

In one embodiment of the invention, the method of forming an active layer on the substrate includes forming a plurality of trenches in the substrate.

In one embodiment of the invention, the method of fabricating the non-volatile memory further includes that a cap layer is formed in the top section of the active layer. The material of the cap layer includes silicon nitride.

In one embodiment of the invention, the method of fabricating the non-volatile memory further includes forming a top dielectric layer between the word lines and the charge storage layer. The material of the top dielectric layer includes silicon oxide.

In one embodiment of the invention, the method of fabricating the non-volatile memory further includes forming a bottom dielectric layer between the charge storage layer and the active layer. The material of the bottom dielectric layer includes silicon oxide.

In one embodiment of the invention, the material of the charge storage layer includes silicon nitride, tantalum silicon oxide, strontium silicon titanate or hafnium silicon oxide.

In one embodiment of the invention, the material of the device isolation layer includes silicon oxide.

In one embodiment of the invention, the method of fabricating the non-volatile memory includes the following steps. A portion of the charge storage layer is removed to form a plurality of openings. The openings are arranged in parallel in the column direction and expose the surface of the active layer. A select gate dielectric layer is formed on the active layer surface exposed by the openings. Afterwards, in the step of patterning the conductive layer to form the word lines, select gate lines are simultaneously formed on each of the openings. Select units are formed in the intersections between the select gate lines and the active layer.

In one embodiment of the invention, the method of forming a select gate dielectric layer on the active layer surface exposed by the openings includes performing a thermal oxidation process.

In one embodiment of the invention, the method of forming an active layer on the substrate includes forming a plurality of trenches in the substrate.

In the non-volatile memory of the invention, since the control gate of the memory cells straddles the active layer, the channel width of the memory cells can be determined by the height of the active layer. Hence, the size of each memory cell can be reduced so as to increase the overall level of integration of the devices.

Moreover, in the non-volatile memory of the invention, the control gate covers the two side walls of the active layer; in other words, both sides of the active layer may serve as channels for the memory cells. Therefore, compared with the conventional stacked memory cell, the memory cell of the invention can obtain larger read currents when performing a reading operation in the memory cell so that the efficiency of the devices can be increased.

Additionally, in the non-volatile memory of the invention, as the charge storage layers are disposed on the sidewalls of the active layer and located between the control gate and the active layer, all the charge storage layers on the sidewalls of the active layer may store charges. Through proper operations, one-bit data, two-bit data and multi-bit data may be stored in a single memory cell.

In the non-volatile memory of the invention, since the outermost two memory cells in each of the memory cell rows serve as select units, the non-volatile memory of the invention does not require disposition of additional select units. Consequently, the storage capability of the devices is increased and the level of integration in the devices is elevated as well.

In the fabricating method of the non-volatile memory of the invention, because the control gates (word lines) of the memory cells are all formed on the active layer and straddle the active layer, the channel width of the memory cell can be determined by the depth of the trench and the thickness of the device isolation layer filled into the trench.

Furthermore, in the fabricating method of the non-volatile memory of the invention, since the charge storage layer is formed on the sidewalls of the active layer, the size of the memory cell is reduced and the level of integration of the devices is increased.

In order to make the aforementioned and other objects, features and advantages of the present invention more comprehensible, preferred embodiments accompanied with figures are described in detail below.

### BRIEF DESCRIPTION OF THE DRAWINGS

FIG. 1A shows a top view of a non-volatile memory according to one preferred embodiment of the present invention.

FIG. 1B is a cross-sectional view showing the structure of FIG. 1A along line A-A′.

FIG. 1C is a cross-sectional view showing the structure of FIG. 1A along line B-B′.

FIG. 1D is a cross-sectional view showing the structure of FIG. 1A along line C-C′.

FIG. 1E is a cross-sectional view showing the structure of FIG. 1A along line D-D′.

FIG. 1F is a cross-sectional view showing the structure of FIG. 1A along line E-E′.

FIG. 2 is a simplified circuit diagram of a non-volatile memory of the invention.

FIG. 3A is a schematic diagram showing a programming operation in the memory cells according to one embodiment of the invention.

FIG. 3B is a schematic diagram showing a reading operation in the memory cells according to one embodiment of the invention.

FIG. 3C is a schematic diagram showing an erasing operation in all memory cells according to one embodiment of the invention.

FIGS. 4A to 4D are flow charts of a fabricating process of a non-volatile memory according to one preferred embodiment of the invention.

FIGS. 5A to 5D are flow charts of a fabricating process of a non-volatile memory according to one preferred embodiment of the invention.

FIGS. 6A to 6D are flow charts of a fabricating process of a non-volatile memory according to one preferred embodiment of the invention.

FIGS. 7A to 7D are flow charts of a fabricating process of a non-volatile memory according to one preferred embodiment of the invention.

### DESCRIPTION OF EMBODIMENTS

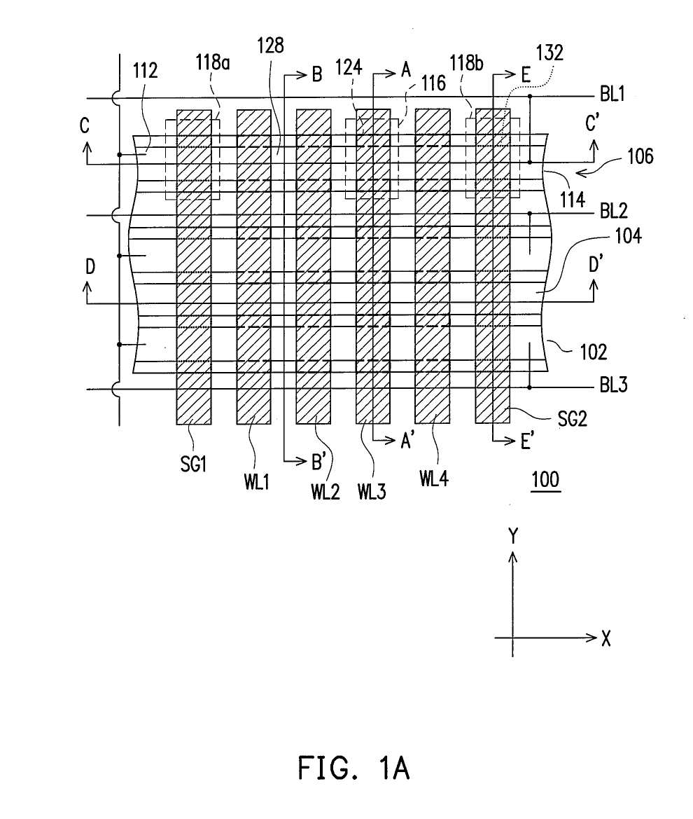

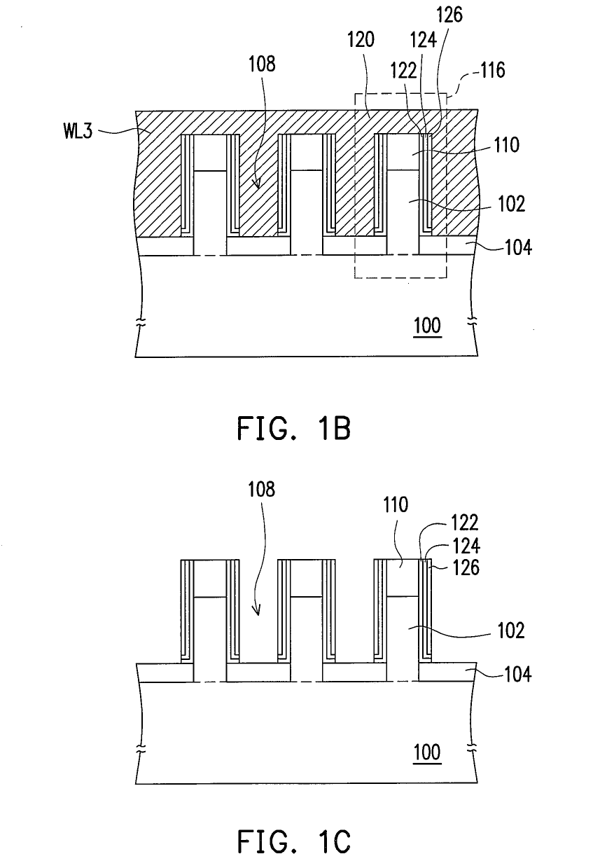

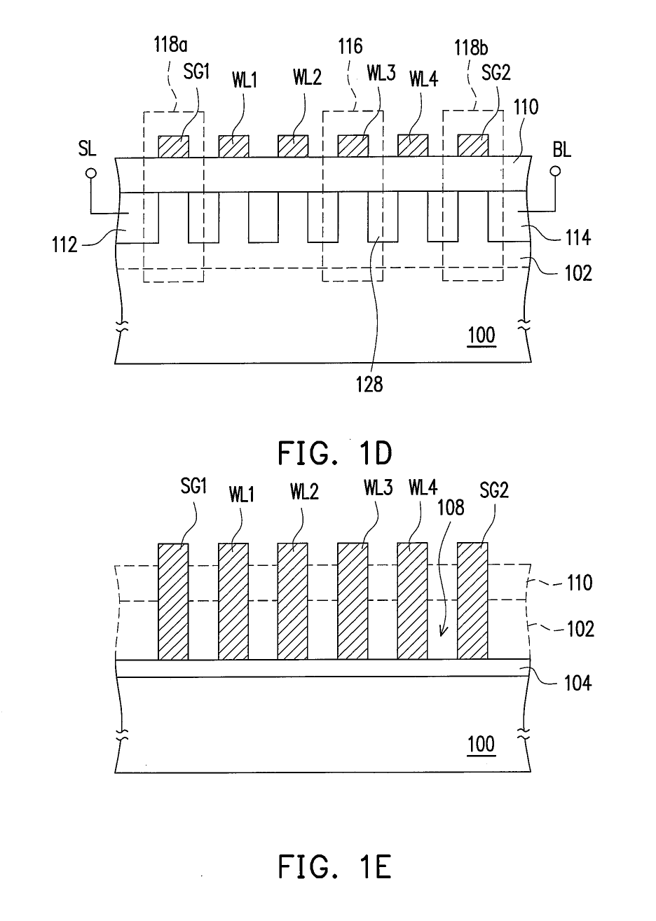

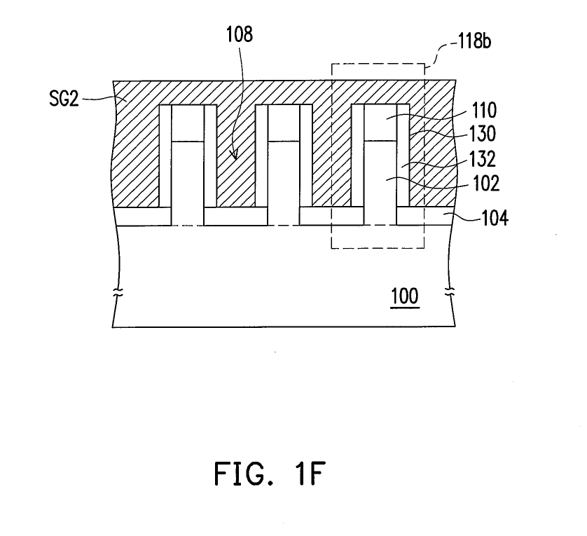

FIG. 1A shows a top view of a non-volatile memory according to one preferred embodiment of the present invention. FIG. 1B is a cross-sectional view showing the structure of FIG. 1A along line A-A′. FIG. 1C is a cross-sectional view showing the structure of FIG. 1A along line B-B′. FIG. 1D is a cross-sectional view showing the structure of FIG. 1A along line C-C′. FIG. 1E is a cross-sectional view showing the structure of FIG. 1A along line D-D′. FIG. 1F is a cross-sectional view showing the structure of FIG. 1A along line E-E′.

First, the non-volatile memory of the invention is described with reference to FIGS. 1A to 1F. The non-volatile memory of the invention includes a substrate 100, a plurality of active layers 102, a plurality of device isolation layers 104, a plurality of memory cell rows 106, a plurality of word lines WL1-WL4, a plurality of bit lines BL1-BL3, a plurality of source lines SL (only one shown in the figures) and a plurality of select gate lines SG1-SG2.

The substrate 100 is, for example, a silicon substrate. The plurality of active layers 102 is disposed on the substrate 100 and protrudes from the surface of the substrate 100. The active layers 102 are, for example, defined by forming a plurality of trenches 108 in the substrate 100. Certainly, the active layers 102 may also be constituted by patterned semiconductor material layers disposed on the substrate 100. The active layers 102 are, for example, arranged in parallel in the X (row) direction and extended to form a grid structure. A cap layer 110 may also be disposed in the top section of the active layers 102. The material of the cap layer 110 is, for example, an insulating material, such as silicon oxide or silicon nitride.

The device isolation layers 104 are respectively disposed on the two sides of the active layers 102, such as disposed in the trenches 108. The surface of the device isolation layers 104 is, for example, lower than the surface of the active layer 102. That is, the active layers 102 protrude from the surface of the device isolation layers 104. The material of the device isolation layers 104 is, for example, silicon oxide. The device isolation layers 104 are used to isolate the substrate 100 from the word lines WL1-WL4 and the substrate 100 from the select gate lines SG1-SG2.

A plurality of memory cell rows 106 is respectively disposed on each of the active layers 102. Each of the memory cell rows 106 includes a source region 112, a drain region 114, a plurality of memory cells 116 and select units 118a and 118b.

The source region 112 and the drain region 114 are, for example, disposed in the active layers 102.

A plurality of memory cells 116 is, for example, connected in series and disposed between the source region 112 and the drain region 114. The source regions 112 of each of the memory cell rows 106 are, for example, connected to the source lines SL. The drain regions 114 of each of the memory cell rows 106 are, for example, respectively connected to bit lines BL1-BL3. Each of the memory cells 116 includes a control gate 120, a bottom dielectric layer 122, a charge storage layer 124, a top dielectric layer 126 and a doped region 128.

The control gate 120 is, for example, disposed on the substrate 100 and crosses over the active layer102. The control gate 120 fills the gaps of the adjacent active layers 102, for example. The material of the control gate 120 includes a conductive material, such as metal, doped polysilicon and polycide. The charge storage layers 124 are, for example, disposed on the sidewalls of the active layer 102 and located between the control gate 120 and the active layer 102. The material of the charge storage layer includes materials that can induce charges into the charge storage layer, such as silicon nitride, tantalum silicon oxide, strontium silicon titanate or hafnium silicon oxide. The bottom dielectric layer 122 is, for example, disposed between the charge storage layer 124 and the active layer 102. The material of the bottom dielectric layer 122 is, for example, silicon oxide. The top dielectric layer 126 is, for example, disposed between the control gate 120 and the charge storage layer 124. The material of the top dielectric layer 124 is, for example, silicon oxide.

The doped region 128 is disposed in the active layer 102 at the two sides of the control gate 120. Each of the memory cells 116 is serially connected by the doped region 128. In a single memory cell 116, the doped region 128 may serve as a source/drain region of the memory cell 116.

The select units 118a and 118b are, for example, respectively disposed between the source region 112 and the memory cell 116 and between the drain region 114 and the memory cell 116. As shown in FIG. 1F, the select unit 118a is, for example, constituted by a select gate 130 and select gate dielectric layers 132. The select gate 130 is, for example, disposed on the substrate 100 and crosses over the active layer 102. The material of the select gate 130 includes conductive materials such as metal, doped polysilicon and polycide. The select gate dielectric layers 132 are, for example, disposed on the sidewalls of the active layer 102 and located between the select gate 130 and the active layer 102. The material of the select gate dielectric layer 132 is, for example, silicon oxide. Certainly, the structures of the select units 118a and 118b are, for example, the same as the structure of the memory cell 116. The outermost two memory cells 116 in the memory cell row 106 are directly used as the select units 118a and 118b. The select gate dielectric layer 132 is constituted by the bottom dielectric layer 122, the charge storage layer 124 and the top dielectric layer 126.

A plurality of word lines WL1-WL4 is, for example, disposed on the substrate 100. The word lines WL1-WL4 are arranged in parallel in the Y (column) direction and electrically connected with the control gate 120 of the memory cell 106 on the same column.

A plurality of bit lines BL1-BL3 is disposed in parallel on the substrate 100. The bit lines are arranged in parallel in the X (row) direction and electrically connected with the drain region 114 in the same memory cell row 106.

A plurality of source lines SL is disposed in parallel on the substrate 100. The source lines SL are arranged in parallel in the Y (column) direction and electrically connected with the source region 112 on the same memory cell column 106.

A plurality of select gate lines SG1 and SG2 is, for example, disposed on the substrate 100. The select gate lines SG1 and SG2 are arranged in parallel in the Y (column) direction and electrically connected with the select gate on the same column.

In the non-volatile memory of the invention, since the control gate 120 of the memory cell 106 straddles the active layer 102, the channel width of the memory cells 106 can be determined by the height of the active layer 102. Hence, the size of each memory cell is reduced so that the overall level of integration of the devices is increased.

Moreover, in the non-volatile memory of the invention, the control gate 120 covers the two side walls of the active layer 102; in other words, both sides of the active layer 102 may serve as channels for the memory cells. Therefore, compared with the conventional stacked memory cell, the memory cell of the invention can obtain larger read currents when performing a reading operation in the memory cell so that the efficiency of the devices is elevated.

Additionally, in the non-volatile memory of the invention, as the charge storage layer 124 is disposed on the sidewalls of the active layer 102 and located between the control gate 120 and the active layer 102, all the charge storage layers 124 on the sidewalls of the active layer 102 may store charges. Through proper operations, one-bit data, two-bit data and multi-bit data may be stored in a single memory cell.

In the non-volatile memory of the invention, since the outermost two memory cells in each of the memory cell rows 106 serve as select units, the non-volatile memory of the invention does not require additional select units to be disposed. Consequently, the storage capability of the devices is increased and the level of integration in the devices is elevated as well.

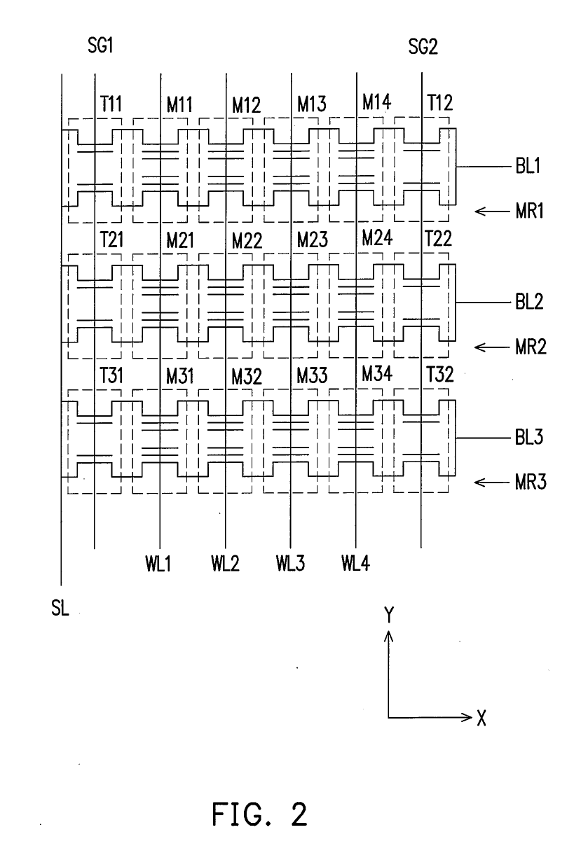

FIG. 2 is a simplified circuit diagram of the non-volatile memory of the invention.

Referring to FIG. 2, the non-volatile memory of the invention is, for example, a memory cell array constituted by a plurality of memory cell rows MR1-MR3.

Each of the memory cell rows MR1-MR3 is disposed on the substrate. Each of the memory cell rows MR1-MR3 includes a plurality of memory cells M11-M34 and select units T11-T32 serially connected between the drain region and the source region. For example, the memory cell row MR1 includes a select unit T11, memory cells M11-M14 and a select unit T12. Similarly, the memory cell row MR3 includes a select unit T31, memory cells M31-M34 and a select unit T32. In the present embodiment, 4 memory cells serially connected between the drain region and the source region are used as an example for illustration herein. Obviously, the number of serially connected memory cells can be adjusted to properly meet actual needs. For example, one memory cell row may include a total of 32 to 64 serially connected memory cells. Furthermore, since the control gate of the memory cells M11-M34 of the invention straddles the active layer, the memory cells M11-M34 are, for example, constituted by two serially connected memory transistors. Similarly, the select gates of the select units T11-T32 straddle the active layers, and thus the select units T11-T32 are, for example, constituted by two serially connected transistors.

A plurality of word lines WL1-WL4 are arranged in parallel in the column direction and each of the word lines is respectively connected to the control gates of the same memory cell column. For example, the word line WL1 is connected to the control gates of the memory cells M11-M31. The word line WL2 is connected to the control gates of the memory cells M12-M32. Similarly, the word line WL4 is connected to the control gates of the memory cells M14-M34. A plurality of bit lines BL1-BL3 are arranged in parallel in the row direction and respectively connected with the drain regions of the same memory cell rows MR1-MR3. A plurality of source lines SL is arranged in parallel in the column direction and electrically connected with the source regions of the same memory cell columns MR1-MR3.

A plurality of select gate lines SG1 and SG2 are arranged in parallel in the column direction and electrically connected with the select gates of the select units T11-T32 on the same column. For example, the select gate line SG1 is connected with the select gates of the select units T11-T31. The select gate line SG2 is connected with the select gates of the select units T12-T32.

Next, the operation modes of the non-volatile memory array of the invention are described herein including a programming, an erasing and a reading operations. One preferred embodiment is provided to illustrate the operation of the non-volatile memory of the invention. However, the operation mode of the non-volatile memory of the invention is not limited to these operations.

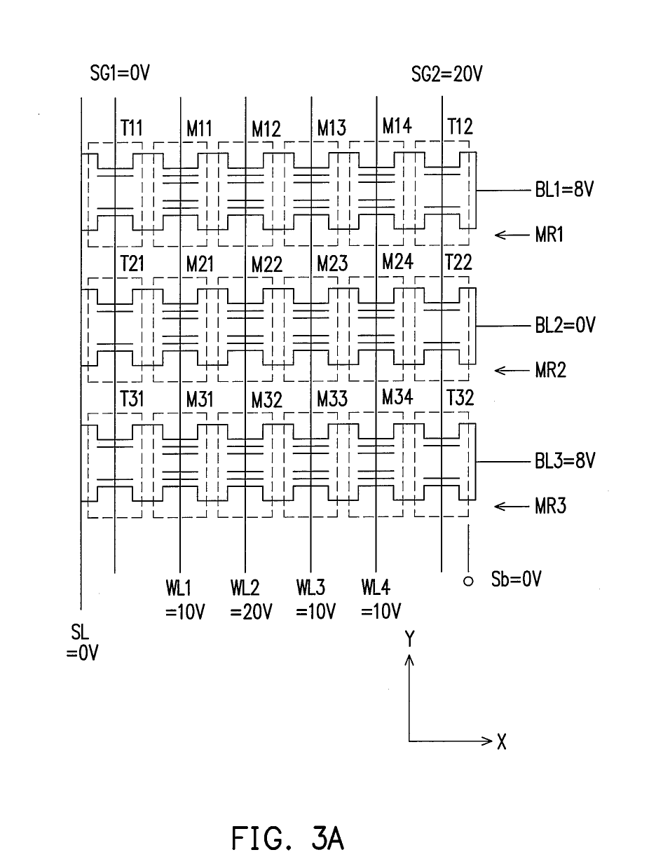

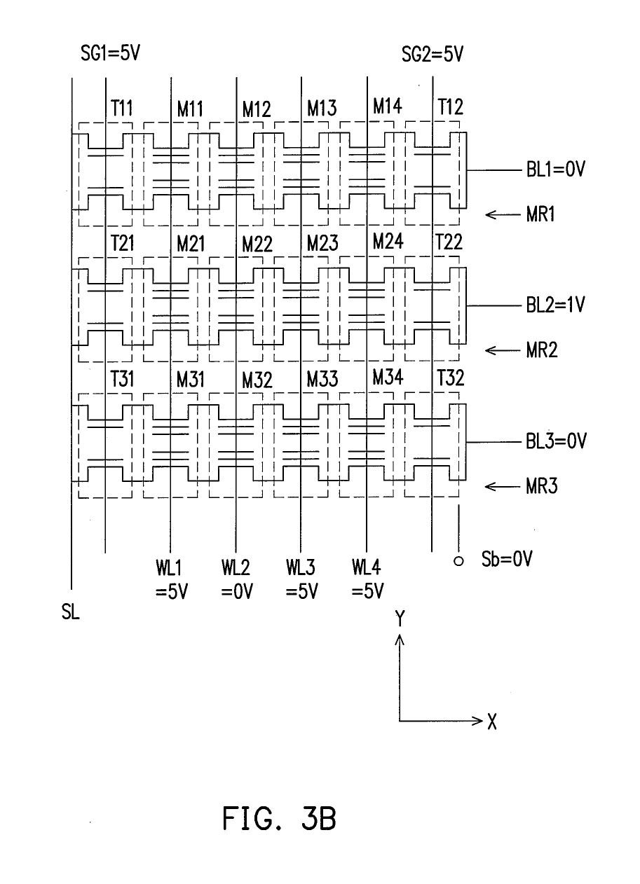

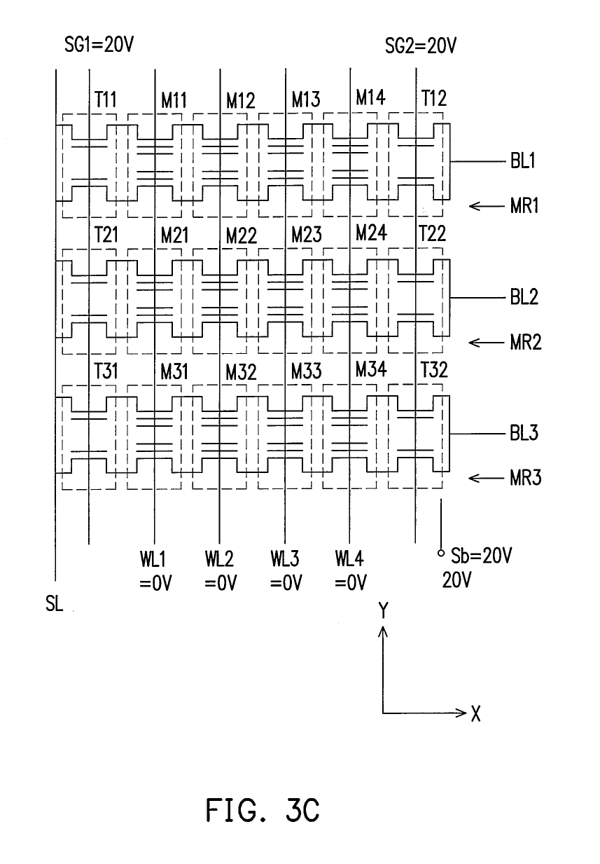

FIG. 3A is a schematic diagram showing a programming operation in the memory cells according to one embodiment of the invention. FIG. 3B is a schematic diagram showing a reading operation in the memory cells according to one embodiment of the invention. FIG. 3C is a schematic diagram showing an erasing operation in all memory cells according to one embodiment of the invention. A memory cell M22 is used as one example to further illustrate as follows.

Referring to FIG. 3A, when the memory cell M22 in the selected memory cell row MR2 is programmed, a voltage Vp1 is applied to the selected bit line BL2. A voltage Vp2 is applied to the non-selected bit lines BL1 and BL3. A voltage Vp3 is applied to the select gate line SG1. A voltage Vp4 is applied to the selected gate line SG2. A voltage Vp5 is applied to the word line WL2 coupled with the selected memory cell M22. A voltage Vp6 is applied to the non-selected word lines WL1, WL3 and WL4. A voltage Vp7 is applied to the source line SL. A voltage about 0 volt is, for example, applied on a substrate Sb. The selected memory cell M22 is programmed by F-N tunneling effect.

Since the voltage difference between the voltages Vp5 and Vp1 is sufficient to trigger the F-N tunneling effect, the voltage difference between the voltages Vp5 and Vp1 needs to be about 12-20 volts. In the present embodiment, the voltage Vp5 is, for example, about 20 volts and the voltage Vp1 is, for example, about 0 volt.

A select transistor ST22 needs to be in the switched-on state, and thus the voltage Vp4 needs to be larger than or equal to the threshold voltage of the select transistor ST22. In the present embodiment, the voltage Vp4 is, for example, about 20 volts. A select transistor ST21 needs to be in the switched-off state, and thus the voltage Vp3 needs to be smaller than the threshold voltage of the select transistor ST21. In the present embodiment, the voltage Vp3 is, for example, about 0 volt.

Moreover, in order to prevent the other non-selected memory cells M12-M32 of the common word line WL2 from being interfered by the programming, the voltage Vp2 may also be applied to the other non-selected bit lines. It is necessary that the voltage Vp2 render the voltage difference between the voltages Vp5 and Vp2 insufficient to trigger the F-N tunneling effect. Hence, the voltage Vp2 is, for example, about 8 volts.

All the channels of the other non-selected memory cells M21, M23 and M24 in the memory cell row MR2 need to be in the switched-on state. Therefore, the voltage Vp6 is at least bigger than or equal to the threshold voltage of the memory cells M21, M23 and M24. In the present embodiment, the voltage Vp6 is, for example, about 10 volts. The voltage Vp7 is, for example, about 0 volt.

Under the forward-biased condition, a big electrical field can be built between the control gate of the selected memory cell M22 and the substrate. As a result, electrons are injected through the channels into the charge storage layer by the channel F-N tunneling effect. The memory cells M11-M34 are, for example, constituted by two serially connected transistors and electrons can be stored in all the charge storage layers of the two memory transistors of the selected memory cells M22.

During the aforementioned programming operation, the memory cells M12 and M32 that share the common word line WL2 are not programmed. This is because a voltage of 8 volts is applied to the non-selected bit lines BL1 and BL3 such that the electrical field between the control gate and the channels is insufficient to trigger the channel F-N tunneling effect. Conceivably, the memory cells M12 and M32 are not programmed.

In addition, a voltage of 10 volts is applied to the non-selected word lines WL1, WL3 and WL4. The voltage is merely used to open the channels of the memory cells and insufficient to trigger the channel F-N tunneling effect. Hence, the memory cells M11-M31, M13-33 and M14-M34 connected with the non-selected word lines WL1, WL3 and WL4 are not programmed.

Although the aforementioned programming operation is performed on a single memory cell in the memory device array, the programming of the non-volatile memory of the invention may also be performed in units such as byte, sector or block by controlling each of the word lines, select gate lines and bit lines.

Referring to FIG. 3B, when the memory cell M22 in the selected memory cell row MR2 is read, a voltage Vr1 is applied to the selected bit line BL2. A voltage Vr2 is applied to the non-selected bit lines BL1 and BL3. A voltage Vr3 is applied to the select gate line SG1. A voltage Vr4 is applied to the select gate line SG2. A voltage Vr5 is applied to the word line WL2 coupled with the selected memory cell M22. A voltage Vr6 is applied to the non-selected word lines WL1, WL3 and WL4. A voltage about 0 volt is, for example, applied on a substrate Sb.

The voltage Vr1 is a reading bias applied to the selected bit line BL2. In the present embodiment, the voltage Vr1 is, for example, about 1 volt. The voltage Vr2 is, for example, about 0 volt.

Since the select transistor ST21 and the select transistor ST22 need to be in the switched-on state, the voltages Vr3 and Vr4 need to be larger than or equal to the threshold voltages of the select transistors ST21 and ST22. In the present embodiment, the voltage Vr3 and the voltage Vr4 is, for example, about 5 volts.

All the channels of the other non-selected memory cells M21, M23 and M24 in the memory cell row MR2 need to be in the switch-on state. Therefore, the voltage Vr6 is at least bigger than or equal to the threshold voltages of the memory cells M21, M23 and M24. In the present embodiment, the voltage Vr6 is, for example, about 5 volts.

Under the aforementioned forward-biased condition, the digital data stored in the memory cells may be determined by detecting the currents in the channels of the memory cells.

Moreover, each of the memory cells M11-M34 of the invention is respectively constituted by two serially connected memory transistors. Therefore, larger read currents can be obtained when reading the selected memory cell M22 and the efficiency of the devices is elevated.

The method of erasing the non-volatile memory array of the invention is described hereinafter. The erasing method disclosed by the invention takes the erasure of the entire non-volatile memory array as an example for illustration.

Referring to FIG. 3C, when erasing a memory unit array, a bias voltage Ve1 is applied to all the word lines WL1-WL4. A bias voltage Ve2 is applied to the substrate Sb. The source line SL and the bit lines BL1-BL3 are floated. Since the voltage applied between the word lines WL1-WL4 and the substrate Sb is sufficient to establish a large electrical field therebetween, electrons are ejected from the charge storage layer to inject into the substrate Sb by the channel F-N tunneling effect and then removed. A bias voltage Ve3 may also be applied to the select gate lines SG1-SG2. In the present embodiment, the voltage Ve1 is, for example, about 0 volt. The voltage Ve2 is, for example, about 20 volts. The voltage Ve3 is, for example, about 20 volts.

In addition, when operations are performed in the non-volatile memory of the invention, electrons are injected through the channels into the charge storage layer by the channel F-N tunneling effect so that the memory cells are programmed. And electrons are injected from the charge storage layer into the substrate by F-N tunneling effect so that the memory cells are erased. During the programming operation, the channel F-N tunneling effect with a higher efficiency of injecting electrons is utilized to lower the currents of the memory cells and increase the operation speed. Moreover, since both the programming and erasing operations utilize the F-N tunneling effect to proceed, the current consumption is small and the power consumption of the entire memory device is substantially reduced.

The fabricating method of a non-volatile memory of the invention is described hereinafter.

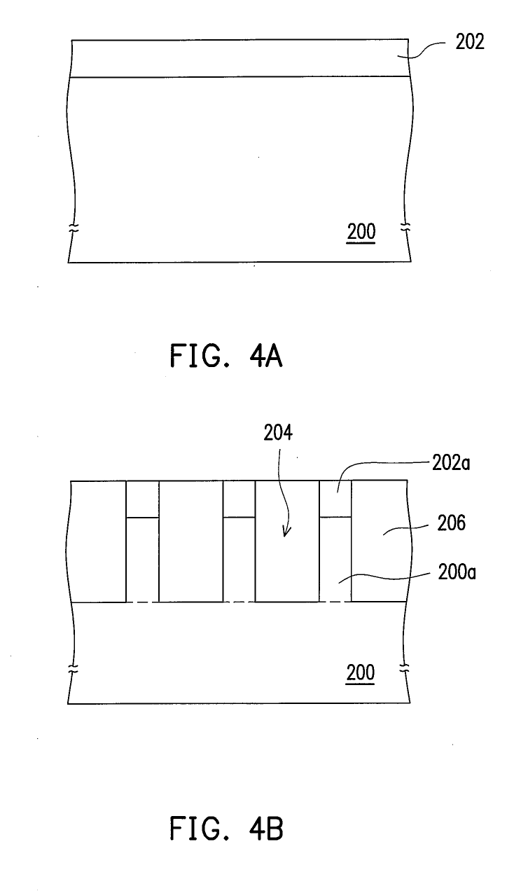

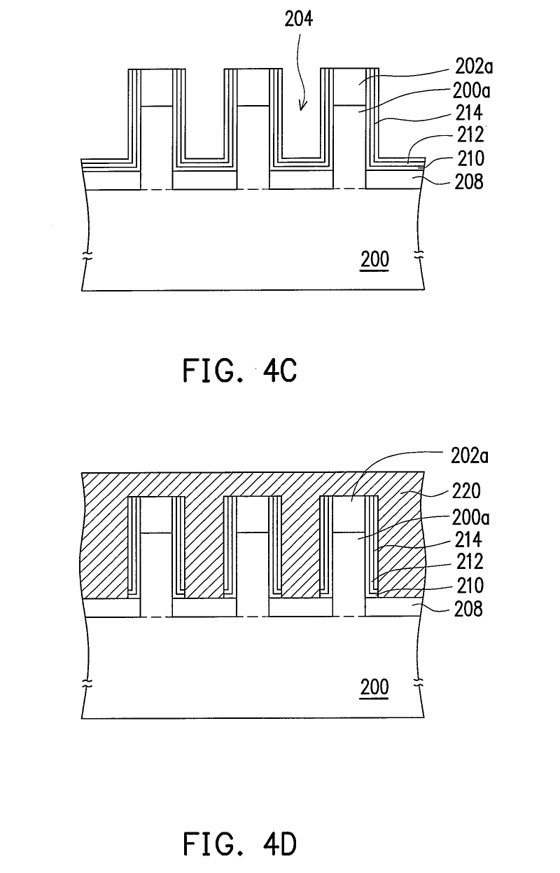

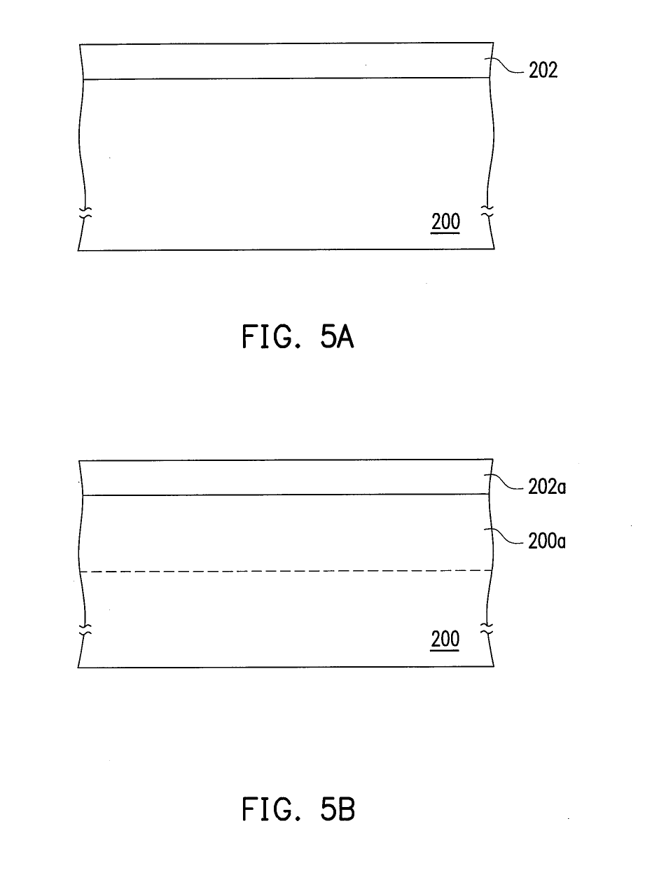

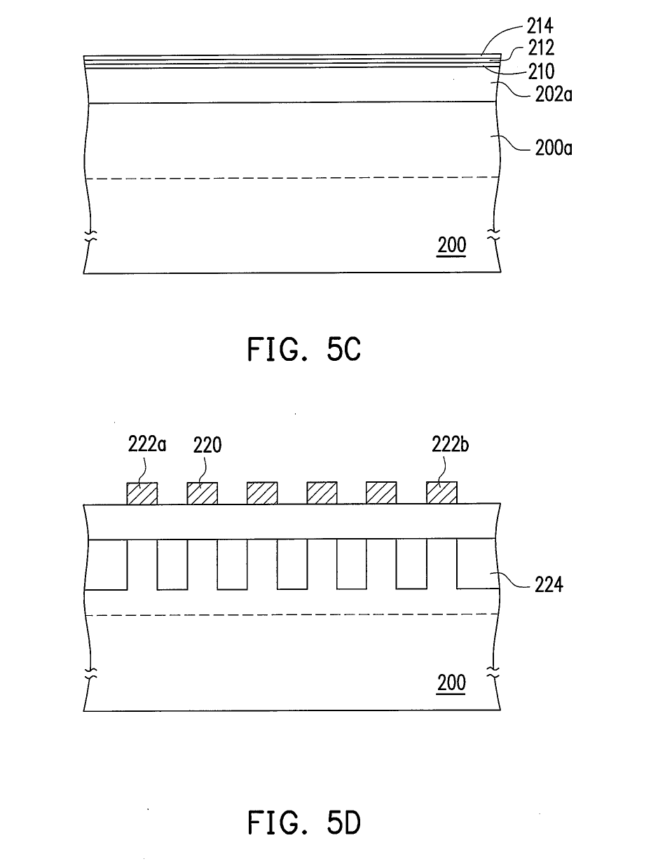

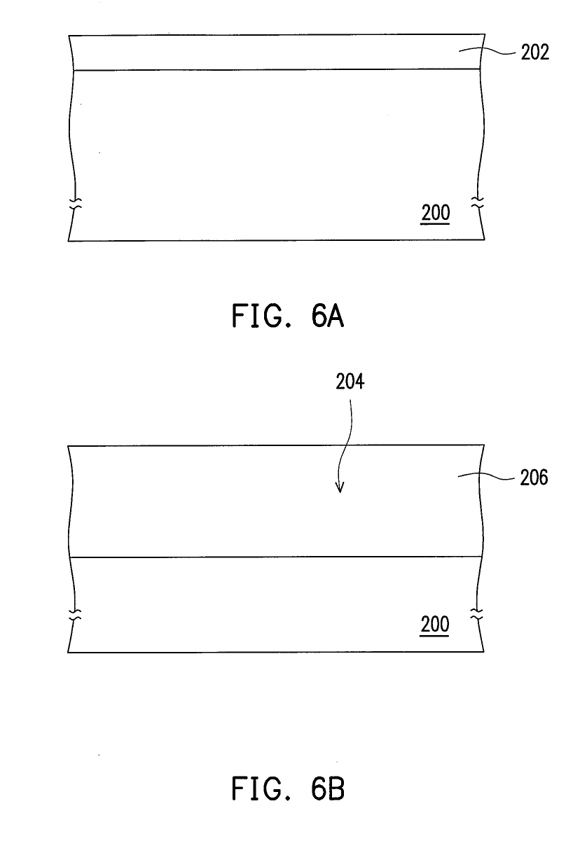

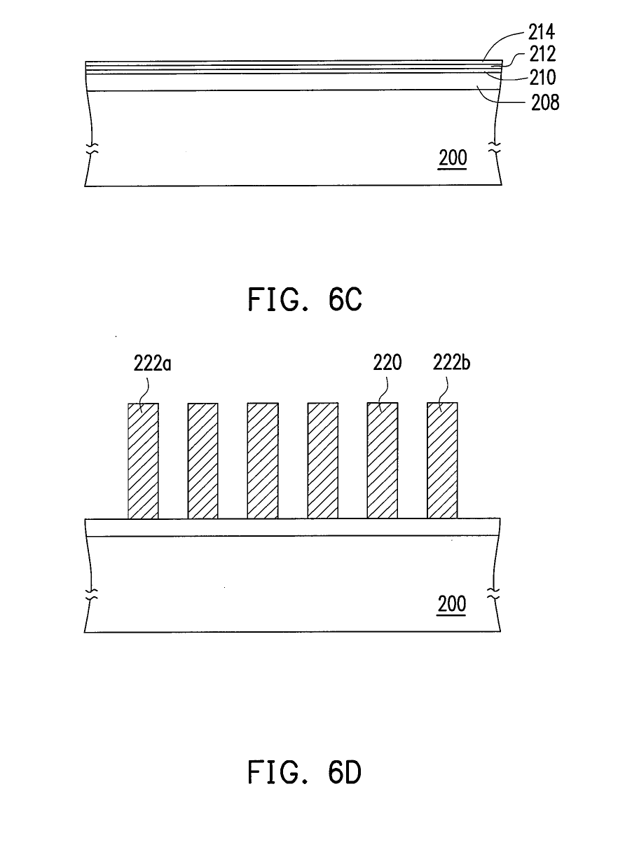

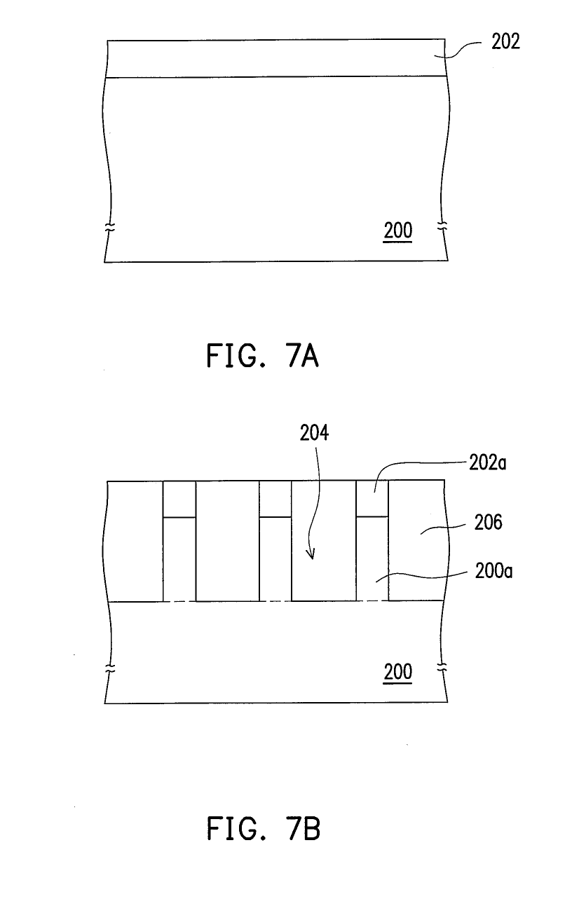

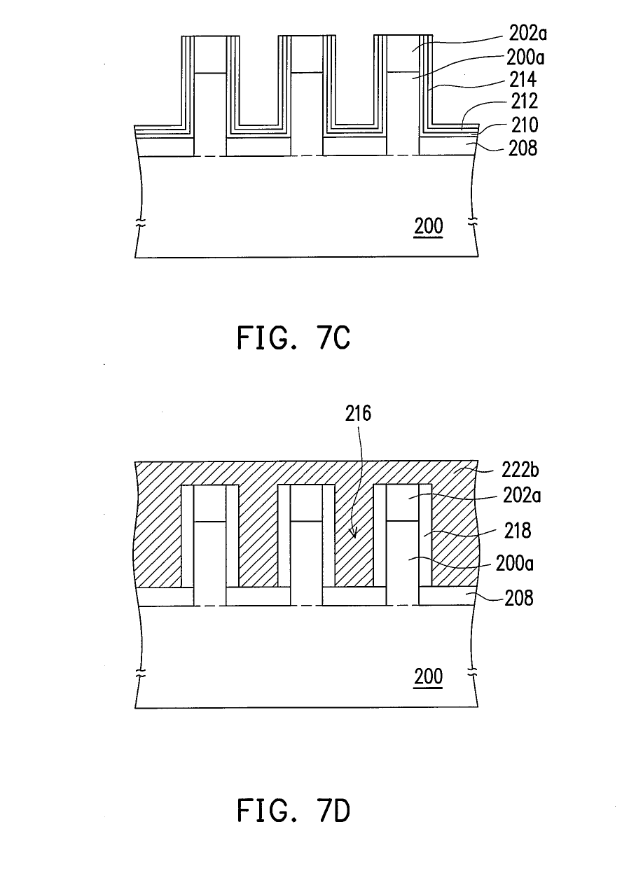

FIGS. 4A to 4D, 5A to 5D, 6A to 6D and 7A to 7D are flowcharts of a fabricating process of a non-volatile memory according to one preferred embodiment of the invention. FIGS. 4A to 4D are cross-sectional views showing the structure of FIG. 1A along line A-A′. FIGS. 5A to 5D are cross-sectional views showing the structure of FIG. 1A along line C-C′. FIGS. 6A to 6D are cross-sectional views showing the structure of FIG. 1A along line D-D′. FIGS. 7A to 7D are cross-sectional views showing the structure of FIG. 1A along line E-E′.

First, referring to FIGS. 4A, 5A, 6A and 7A, a substrate 200 such as a silicon substrate is provided. Then, a mask layer 202 is formed on the substrate 200. The material of the mask layer 202 is, for example, silicon nitride. The method of forming the mask layer 202 is, for example, performing a chemical vapor deposition (CVD) process. Obviously, a pad oxide layer (not shown) may also be formed between the mask layer 202 and the substrate 200 so as to increase the adhesion between the mask layer 202 and the substrate 200. The material of the pad oxide layer is, for example, silicon oxide. The method of forming the pad oxide layer is, for example, performing a thermal oxidation process.

Referring to FIGS. 4B, 5B, 6B and 7B, afterwards, the mask layer 202 is patterned to form a patterned mask layer 202a. The patterned mask layer 202a serves as a mask to remove a portion of the substrate 200. Trenches 204 are formed in the substrate 200 and thus define active layers 200a. The method of removing a portion of the substrate 200 includes performing a reactive ion etching process. The active layers 200a protrude from the surface of the substrate 200 and are arranged in parallel in the row direction. Certainly, the active layers 200a may also be formed by directly forming a semiconductor material layer (not shown) and then patterning the semiconductor material layer.

Next, an insulating material layer 206 is formed on the substrate 200. The material of the insulating material layer 206 is, for example, silicon oxide. The insulating material layer 206 is, for example, formed by performing a chemical vapor deposition (CVD) process. The thickness of the insulating material layer 206 is larger than the summation of the depth of the trench 204 and the thickness of the patterned mask layer 202a. Thereafter, a planarization procedure is performed to planarize the surface of the insulating material layer 206. The method of planarizing the surface of the insulating material layer 206 may include performing a chemical-mechanical polishing process or an etching back process. During the planarization of the surface of the insulating material layer 206, the mask layer 202a may serve as a polishing/etching stop layer.

Afterwards, referring to FIGS. 4C, 5C, 6C and 7C, a portion of the insulating material layer 206 is removed to render the upper surface of the insulating material layer 206 lower than the upper surface of the substrate 200. A device isolation layer 208 is formed at the two sides of the active layer 200a. The method of removing a portion of the insulating material layer includes performing an etching back process. The height of the active layer 200a can be determined by the depth of the trench 204 and the thickness of the device isolation layer 208. The height of the active layer 200a will affect the channel width of a subsequently formed memory cell.

Next, a bottom dielectric layer 210, a charge storage layer 212 and a top dielectric layer 214 are sequentially formed on the substrate 200. The material of the bottom dielectric layer 212 is, for example, silicon oxide. The bottom dielectric layer 212 is, for example, formed by a thermal oxidation process or a chemical vapor deposition (CVD) process. The material of the charge storage layer 214 includes charge-trapping materials (such as silicon nitride, tantalum silicon oxide, strontium silicon titanate or hafnium silicon oxide) or other materials that can store charges. The method of forming the charge storage layer 212 includes performing a chemical vapor deposition (CVD) process. The material of the top dielectric layer 214 is, for example, silicon oxide. The method of forming the top dielectric layer 214 is, for example, performing a chemical vapor deposition (CVD) process. Certainly, the materials of the bottom dielectric layer 210 and the top dielectric layer 214 may also be other dielectric materials. In another embodiment, the bottom dielectric layer 210 and/or the top dielectric layer 214 may also not be formed.

Next, referring to FIGS. 4D, 5D, 6D and 7D, a portion of the bottom dielectric layer 210, the charge storage layer 212 and the top dielectric layer 214 are removed so that a plurality of openings 216 is formed in the stacked layers constituted by the bottom dielectric layer 210, the charge storage layer 212 and the top dielectric layer 214. The openings 216 are arranged in parallel in the column direction and expose the surface of the active layer 200a. In other words, the openings 216 expose the area to be formed as a select unit. The method of forming the openings 216 may include the following steps. First, a patterned photoresist layer (not shown) is formed on the substrate 200. The patterned photoresist layer exposes the area to be formed as a select unit. Then, a portion of the bottom dielectric layer 210, the charge storage layer 212 and the top dielectric layer 214 is removed by using the patterned photoresist layer as a mask. Afterwards, the patterned photoresist layer is removed. A select gate dielectric layer 218 is then formed on the surface of the active layer 200a exposed by the openings 216.

Obviously, in another embodiment, the bottom dielectric layer 210, the charge storage layer 212 and the top dielectric layer 214 located within the area designated for forming a select unit therein may also not be removed and the select gate dielectric layer 218 is correspondingly not formed either. Thus, the bottom dielectric layer 210, the charge storage layer 212 and the top dielectric layer 214 are directly used as the select gate dielectric layer of the select unit.

Thereafter, a conductive layer (not shown) is formed on the substrate 200. The material of the conductive layer is, for example, doped polysilicon. The method of forming the conductive layer is, for example, forming an undoped polysilicon layer by a chemical vapor deposition (CVD) process and then performing an ion implantation process to obtain doped polysilicon. The conductive layer may also be formed by performing an in-situ dopant implantation process and then a chemical vapor deposition (CVD) process to directly form the doped polysilicon.

The conductive layer is patterned to form a plurality of word lines 220 and select gate lines 222a and 222b. The plurality of word lines 220 and the select gate lines 222a and 222b are arranged in parallel in the column direction. Then, a plurality of doped regions 224 are formed in the active layer 202a at the two sides of the word lines 220 and the select gate lines 222a and 222b. The doped regions 224 are, for example, formed by performing an ion implantation process. Memory cells are respectively formed in the intersection between the word lines 220 and the active layers 200a. Portions of the active layers 200a where the word lines 220 straddle are respectively the control gates of the memory cells. The doped regions 224 at the two sides of the control gates serve as the source/drain regions of the memory cells. The select gate lines 222a and 222b are formed on each of the openings 216. Select units are respectively formed in the intersections between the select gate lines 222a and 222b and the active layers 200a. The portions of the active layers 200a where the select gate lines 222a and 222b cross over serve as select gates of the select units respectively. The subsequent process of fabricating the non-volatile memory is well-known to people skilled in the art and is not to be reiterated herein. In the fabricating method of the non-volatile memory of the invention, the control gates (word lines 220) of the memory cells are all formed on the active layers 200a and straddle the active layers 200a. Hence, the channel width of the memory cells can be determined by the depth of the trench 204 and the thickness of the device isolation layer 208 filled into the trench 204.

Furthermore, the charge storage layer 212 is formed on the sidewalls of the active layers 200a. The size of the memory cells is reduced so that the level of integration of the devices is increased. Additionally, the channel length of the memory cells can also be adjusted by controlling the depth of the trench so that the abnormal electrical punch-through in the memory cells is avoided. Moreover, the fabricating process of the non-volatile memory of the present invention is relatively simpler, and the level of integration in the memory array can be increased.

In the aforementioned embodiment, 4 memory cell structures are described as examples. Certainly, any number of memory cells may be formed by the fabricating method of the non-volatile memory in the invention to properly meet actual demands. For example, 32 to 64 memory cell structures may be connected in series to a single word line.

In summary, in the non-volatile memory of the invention, since the control gate of the memory cell straddles the active layer, the channel width of the memory cell can be determined by the height of the active layer. Hence, the size of each of the memory cells is reduced and the overall level of integration of the devices is increased.

Moreover, in the non-volatile memory of the invention, the control gate covers the two sidewalls of the active layer; in other words, both sides of the active layer may serve as channels for the memory cells. Therefore, compared with the conventional stacked memory cells, the memory cells of the invention obtain larger read currents when a reading operation is performed in the memory cells so that the efficiency of the devices is increased.

Furthermore, in the non-volatile memory of the invention, as the charge storage layer is disposed on the sidewalls of the active layer and located between the control gate and the active layer, all the charge storage layers on the sidewalls of the active layer may store charges. Through proper operations, one-bit data, two-bit data or multi-bit data may be stored in a single memory cell.

In the non-volatile memory of the invention, since the outermost two memory cells in each of the memory cell rows serve as select units, the non-volatile memory of the invention does not require additional select units to be disposed. Consequently, the storage capability of the devices is increased and the level of integration among the devices is elevated as well.

In the operation methods of the non-volatile memory of the invention, electrons are injected into the charge storage layer by the channel F-N tunneling effect while performing a programming operation on the memory cells. The electrons are also ejected from the charge storage layer to inject into the substrate by the F-N tunneling effect while performing an erasing operation on the memory cells. During the programming operation, using the channel F-N tunneling effect with a higher electron injection efficiency can lower the memory cell currents and increase the operating speed. Moreover, with both the programming and erasing operations driven by the F-N tunneling effect, the current consumption is lowered and the power consumption of the entire memory device is effectively reduced. Moreover, since each of the memory cells is constituted by two serially connected memory transistors, when reading a selected memory cell, larger read currents may be obtained so as to increase the efficiency of the devices.

In the fabricating method of the non-volatile memory of the invention, because the control gates (word lines) of the memory cells are all formed on the active layer and cross over the active layers, the channel width of the memory cell can be determined by the depth of the trench and the thickness of the device isolation layer filled into the trench.

Furthermore, in the fabricating method of the non-volatile memory of the invention, since the charge storage layer is formed on the sidewalls of the active layer, the size of the memory cell is reduced and the level of integration of the devices is elevated.

Although the present invention has been disclosed above by the embodiments, they are not intended to limit the present invention. Anybody ordinarily skilled in the art can make some modifications and alterations without departing from the spirit and scope of the present invention. Therefore, the protecting range of the present invention falls in the appended claims.

What is claimed is:

1. A non-volatile memory, comprising:
a substrate;
an active layer, disposed on the substrate and protruding from the surface of the substrate;
a plurality of device isolation layers, respectively disposed at the two sides of the active layer, wherein the surface of the device isolation layers is lower than the surface of the active layer;
at least one memory cell, disposed on the substrate, the memory cell comprising:
a control gate, disposed on the substrate and crossing over the active layer;
a charge storage layer, disposed on the sidewalls of the active layer and located between the control gate and the active layer;
a cap layer, disposed on the top section of the active layer and located between the control gate and the active layer; and
a source/drain region, disposed in the active layer at the two sides of the control gate.

2. The non-volatile memory of claim 1, further comprising a top dielectric layer, disposed between the control gate and the charge storage layer.

3. The non-volatile memory of claim 2, wherein the material of the top dielectric layer comprises silicon oxide.

4. The non-volatile memory of claim 1, further comprising a bottom dielectric layer, disposed between the charge storage layer and the active layer.

5. The non-volatile memory of claim 4, wherein the material of the bottom dielectric layer comprises silicon oxide.

6. The non-volatile memory of claim 1, wherein the material of the charge storage layer comprises silicon nitride, tantalum silicon oxide, strontium silicon titanate or hafnium silicon oxide.

7. The non-volatile memory of claim 1, wherein the material of the device isolation layer comprises silicon oxide.

8. A non-volatile memory, comprising:
a substrate;
a plurality of active layers, disposed on the substrate and protruding from the substrate surface, wherein the active layers are arranged in parallel in the row direction;
a plurality of device isolation layers, respectively disposed on the two sides of the active layers, wherein the surface of the device isolation layers is lower than the surface of the active layers;
a plurality of memory cell rows, respectively disposed on the active layers, wherein each of the memory cell rows comprises:
a source region and a drain region, disposed in the active layer;
a plurality of memory cells, serially connected and disposed between the source region and the drain region, wherein each of the memory cells comprises:
a control gate, disposed on the substrate and crossing over the active layer;
a charge storage layer, disposed on the sidewalls of the active layer and located between the control gate and the active layer;
a doped region, disposed in the active layer at the two sides of the control gate;
a plurality of word lines, disposed on the substrate, wherein the word lines are arranged in parallel in a column direction and electrically connected with the control gates on the same column;
a plurality of bit lines, disposed in parallel on the substrate, wherein the bit lines are arranged in parallel in the row direction and electrically connected with the drain region in the same memory cell row; and
a plurality of source lines, disposed in parallel on the substrate, wherein the source lines are arranged in parallel in the column direction and electrically connected with the source region on the same memory cell column.

9. The non-volatile memory of claim 8, wherein the outermost memory cell of the memory cell rows serves as a select unit.

10. The non-volatile memory of claim 9, wherein the word line connected with the select units serves as a select gate line.

11. The non-volatile memory of claim 8, wherein the memory cell rows further comprise two select units respectively disposed between the source region and the memory cells and between the drain region and the memory cells.

12. The non-volatile memory of claim 11, wherein each of the select units comprises:
a select gate, disposed on the substrate and crossing over the active layer; and
a select gate dielectric layer, disposed on the sidewalls of the active layer and located between the select gate and the active layer.

13. The non-volatile memory of claim 12, further comprising a plurality of select gate lines disposed on the substrate, wherein the select gate lines are arranged in parallel in the column direction and electrically connected with the select gates on the same column.

14. The non-volatile memory of claim 12, wherein the material of the select gate dielectric layer comprises silicon oxide.

15. The non-volatile memory of claim 8, further comprising a top dielectric layer, disposed between the control gate and the charge storage layer.

16. The non-volatile memory of claim 15, wherein the material of the top dielectric layer comprises silicon oxide.

17. The non-volatile memory of claim 8, further comprising a bottom dielectric layer, disposed between the charge storage layer and the active layer.

18. The non-volatile memory of claim 17, wherein the material of the bottom dielectric layer comprises silicon oxide.

19. The non-volatile memory of claim 8, wherein the material of the charge storage layer comprises silicon nitride, tantalum silicon oxide, strontium silicon titanate or hafnium silicon oxide.

20. The non-volatile memory of claim 8, wherein the material of the device isolation layer comprises silicon oxide.

21. The non-volatile memory of claim 8, further comprising a cap layer, disposed in the top section of the active layer and located between the control gate and the active layer.

22. The non-volatile memory of claim 21, wherein the material of the cap layer comprises silicon nitride.

23. A method of fabricating a non-volatile memory, comprising:
providing a substrate;
forming an active layer on the substrate, wherein the active layer protrudes from the substrate surface;
forming a plurality of device isolation layers at the two sides of the active layer, wherein the surface of the device isolation layers is lower than the surface of the active layer;
forming a charge storage layer on the substrate;
forming a control gate on the substrate, wherein the control gate crosses over the active layer; and
forming a source/drain region in the active layer at the two sides of the control gate.

24. The method of fabricating the non-volatile memory of claim 23, wherein the step of forming the active layer on the substrate comprises forming a plurality of trenches in the substrate.

25. The method of fabricating the non-volatile memory of claim 23, further comprising forming a cap layer in the top section of the active layer.

26. The method of fabricating the non-volatile memory of claim 25, wherein the material of the cap layer comprises silicon nitride.

27. The method of fabricating the non-volatile memory of claim 23, further comprising forming a top dielectric layer between the control gate and the charge storage layer.

28. The method of fabricating the non-volatile memory of claim 27, wherein the material of the top dielectric layer comprises silicon oxide.

29. The method of fabricating the non-volatile memory of claim 23, further comprising forming a bottom dielectric layer, disposed between the charge storage layer and the active layer.

30. The method of fabricating the non-volatile memory of claim 29, wherein the material of the bottom dielectric layer comprises silicon oxide.

31. The method of fabricating the non-volatile memory of claim 23, wherein the material of the charge storage layer comprises silicon nitride, tantalum silicon oxide, strontium silicon titanate, hafnium silicon oxide.

32. The method of fabricating the non-volatile memory of claim 23, wherein the material of the device isolation layer comprises silicon oxide.

33. A method of fabricating a non-volatile memory, comprising:
providing a substrate;
forming a plurality of active layers on the substrate, wherein the active layers protrude from the substrate surface and are arranged in parallel in the row direction;
forming a plurality of device isolation layers at the two sides of the active layer, wherein the surface of the device isolation layers is lower than the surface of the active layers;
forming a charge storage layer on the substrate;
forming a conductive layer on the substrate;
patterning the conductive layer to form a plurality of word lines, wherein the word lines are arranged in parallel in the column direction and cross over the active layers; and
forming a plurality of doped regions in the active layer at the two sides of the word lines, wherein a memory cell is formed respectively in the intersections between the word lines and the active layers.

34. The method of fabricating the non-volatile memory of claim 33, wherein the step of forming the active layer on the substrate comprises forming a plurality of trenches in the substrate.

35. The method of fabricating the non-volatile memory of claim 33, further comprising forming a cap layer in the top section of the active layer.

36. The method of fabricating the non-volatile memory of claim 35, wherein the material of the cap layer comprises silicon nitride.

37. The method of fabricating the non-volatile memory of claim 33, further comprising forming a top dielectric layer between the word lines and the charge storage layer.

38. The method of fabricating the non-volatile memory of claim 37, wherein the material of the top dielectric layer comprises silicon oxide.

39. The method of fabricating the non-volatile memory of claim 33, further comprising forming a bottom dielectric layer between the charge storage layer and the active layer.

40. The method of fabricating the non-volatile memory of claim 39, wherein the material of the bottom dielectric layer comprises silicon oxide.

41. The method of fabricating the non-volatile memory of claim 33, wherein the material of the charge storage layer comprises silicon nitride, tantalum silicon oxide, strontium silicon titanate, hafnium silicon oxide.

42. The method of fabricating the non-volatile memory of claim 33, wherein the material of the device isolation layer comprises silicon oxide.

43. The method of fabricating the non-volatile memory of claim 33, further comprising:
removing a portion of the charge storage layer to form a plurality of openings, wherein the openings are arranged in parallel in the column direction and expose the surface of the active layers;
forming a select gate dielectric layer on the surface of the active layers exposed by the openings; and
during the step of patterning the conductive layer to form the word lines, simultaneously forming a select gate line on each of the openings, wherein a select unit is formed respectively in the intersections between the select gate lines and the active layer.

44. The method of fabricating the non-volatile memory of claim 43, wherein the step of forming the select gate dielectric layer on the surface of the active layers exposed by the openings comprises performing a thermal oxidation process.

45. The method of fabricating the non-volatile memory of claim 33, wherein the step of forming the active layer on the substrate comprises forming a plurality of trenches in the substrate.
